(19) United States
(12) Patent Application Publication
(10) Pub. No.: US 2015/0077141 A1
(43) Pub. Date: Mar. 19, 2015

(54) Capacitive sensor for an anti-collision apparatus, and capacitive sensor

(71) Applicant: BROSE FAHRZEUGTEILE GMBH & CO. KOMMANDITGESELLSCHAFT HALLSTADT, Hallstadt (DE)

(72) Inventors: DETLEF RUSS, EBERSDORF (DE); HOLGER WUERSTLEIN, ZEIL AM MAIN (DE); FLORIAN POHL, EBERSDORF (DE); RALF DAIMINGER, BAMBERG (DE); JAN KAISER, BAYREUTH (DE)

(21) Appl. No.: 14/551,584

(22) Filed: Nov. 24, 2014

Related U.S. Application Data
(63) Continuation of application No. PCT/EP2013/001510, filed on May 22, 2013.

(30) Foreign Application Priority Data
May 24, 2012 (DE) 102012010228.3

(51) Int. Cl. G01V 3/08; G01R 27/26; B60R 21/013

(52) U.S. Cl. CPC G01V 3/08; B60R 21/013; G01R 27/2605
USPC 324/676; 324/658

(57) ABSTRACT

A capacitive sensor is configured for detecting an object, in particular for detecting a collision in the case of a movable vehicle part, and an anti-collision apparatus has such a sensor. The sensor has an electrode arrangement with at least one transmitting electrode and at least one or more receiving electrodes. The sensor has a signal generation circuit which is connected upstream of the at least one transmitting electrode. The signal generation circuit generates a transmission signal in the form of a square-wave pulse signal corresponding directly to a pseudo-random bit string.

### CROSS-REFERENCE TO RELATED APPLICATION

This application is a continuation, under 35 U.S.C. §120, of copending international application No. PCT/EP2013/001510, filed May 22, 2013, which designated the United States; this application also claims the priority, under 35 U.S.C. §119, of German patent application No. DE 10 2012 010 228.3, filed May 24, 2012; the prior applications are herewith incorporated by reference in their entirety.

### BACKGROUND OF THE INVENTION

### Field of the Invention

The invention relates to a capacitive sensor for detecting an object, such as a part of a person's body or another such object, and to an anti-collision apparatus having such a sensor.

Capacitive sensors are used in automotive engineering, in particular within an anti-collision apparatus. Such an anti-collision apparatus is generally used to detect an obstacle in an opening area of a vehicle part which is movable between an open position and a closed position with respect to a fixed frame. The vehicle part—also referred to as “adjustment element” below—is a tailgate, in particular. Furthermore, the vehicle part or adjustment element to be monitored may also be a side door, a trunk lid or engine compartment cover, a sliding roof or a folding top. Anti-collision apparatuses are used in this case, in particular, when the respectively associated motor vehicle part is moved by motor.

The space covered by the adjustment element during an adjustment movement is referred to as the opening area. The opening area of the adjustment element includes, in particular, the area of space arranged between a closing edge of the adjustment element and a corresponding edge of the frame on which the closing edge of the adjustment element rests in the closed position.

When closing adjustment elements of a vehicle, such as a tailgate, there is generally the risk of body parts or other items of the adjustment element being trapped between the closing edge of the adjustment element and the bodywork. The anti-collision apparatus which is also referred to as an anti-trapping apparatus in this application is used to avoid such trapping and the resultant risk of personal injury and/or material damage by virtue of the anti-collision apparatus detecting obstacles in the opening area and stopping or reversing the closing movement in this case.

Furthermore, an anti-collision apparatus can also be used to detect obstacles which obstruct the opening of the adjustment element. In this application too, the anti-collision apparatus stops or reverses the movement of the adjustment element if it detects such an obstacle in order to avoid material damage as a result of the adjustment element colliding with the obstacle.

In this case, a distinction is made between indirect and direct anti-collision apparatuses. An indirect anti-collision apparatus detects the collision (in particular trapping) by monitoring an operating variable of the servo motor driving the adjustment element, in particular from an abnormal increase in the motor current or an abnormal decrease in the motor speed. A direct anti-collision apparatus usually comprises one or more sensors which record a measurement variable characteristic of the presence or absence of an obstacle in the opening area as well as an evaluation unit which uses this measurement variable to decide whether an obstacle is present in the opening area and to initiate corresponding countermeasures if necessary. Among the direct anti-collision apparatuses, a distinction is again made between systems with so-called contact sensors which indicate the presence of an obstacle only when the obstacle has already touched the sensor, and systems with contactless sensors which already detect an obstacle at a certain distance from the sensor. The contactless sensors include, in particular, so-called capacitive sensors.

A capacitive sensor comprises an electrode arrangement having one or more electrodes which are used to build up an electric field in the opening area of the adjustment element. An obstacle in the opening area is detected by monitoring the capacitance of the electrode arrangement. In this case, use is made of the fact that an obstacle, in particular a human body part, influences the electric field generated by the sensor and thus influences the capacitance of the electrode arrangement.

In a conventional design of such a capacitive sensor, the electrode arrangement of this sensor comprises at least one transmission electrode, which is connected to a signal generation circuit, and a reception electrode which is connected to a reception circuit. Such a sensor measures the capacitance formed between the transmission electrode and the reception electrode or a measurement variable correlated therewith.

An anti-collision apparatus or anti-trapping apparatus which is provided for monitoring the opening area of a tailgate and has such a sensor is described in the commonly assigned German utility model DE 20 2007 008 440 U1.

As the transmission signal, use is usually made in this case of an electrical alternating signal which oscillates at a predefined transmission frequency. In this case, an electronic resonant circuit is generally used as the signal generation circuit.

In the case of a sensor known from U.S. Pat. No. 7,545,154 B2 and its counterpart European patent EP 1 828 524 B1, the transmission frequency and/or the duty ratio is/are changed in order to be able to better distinguish actual events, which indicate trapping or collision, from interfering events, for example fog or rain. At least two measurements at different transmission frequencies and/or duty ratios are carried out for this purpose. An event is identified as true, that is to say as indicating trapping or collision, when the measured change in the capacitance is substantially the same for all measurements. In contrast, an event is identified as an interfering event when the measured change in the capacitance assumes different values for all measurements.

In order to avoid interference in the reception signal caused by electromagnetic interference sources, a periodic basic signal is subjected to frequency spreading in order to generate the transmission signal by modulating a noise signal onto the basic signal in capacitive sensors. This is described in U.S. Pat. No. 7,944,216 B2 and its counterpart German published patent application DE 10 2007 058 707 A1, as well as in U.S. Pat. No. 6,225,710 B1 and its counterpart European published patent application EP 0 945 984 A2.

However, such sensors disadvantageously have a comparatively complex structure.

### SUMMARY OF THE INVENTION

It is accordingly an object of the invention to provide a capacitive sensor and a collision prevention apparatus with such a sensor which overcomes the above-mentioned and other disadvantages of the heretofore-known devices and methods of this general type and which provides for a capacitive sensor that is not susceptible to interference, but at the same time is particularly simple.

With the foregoing and other objects in view there is provided, in accordance with the invention, a capacitive sensor for detecting an object, in particular for detecting an impending collision with a movable vehicle part in an anti-trapping system. The novel capacitive sensor comprises:

an electrode arrangement having at least one transmission electrode and at least one reception electrode;

a signal generation circuit connected upstream of said at least one transmission electrode, said signal generation circuit being configured to generate a transmission signal in the form of a square-wave pulse signal that directly corresponds to a pseudo-random bit string and to pass the transmission signal to said transmission electrode.

With the above and other objects in view there is also provided, in accordance with the invention, an anti-collision apparatus that comprises a capacitive sensor as described herein.

The sensor according to the invention comprises an electrode arrangement comprising at least one transmission electrode and at least one reception electrode. The sensor also comprises a signal generation circuit which is connected upstream of the at least one transmission electrode and is used to generate a transmission signal for this/these transmission electrode(s). As the transmission signal, a square-wave signal which directly corresponds to a pseudo-random bit string is generated in this case by the signal generation circuit. In this case, the transmission signal is formed from a sequence of clock pulses, in particular. In each clock pulse, the transmission signal has a signal value which corresponds to an associated bit value of the pseudo-random bit string. For example, the transmission signal has a “high” voltage value (“HIGH”) of +5 V, for example, in each clock pulse associated with a “1” value of the pseudo-random bit string, whereas the transmission signal has a “low” voltage value (“LOW”) of 0 V or +0.5 V, for example, in each clock pulse associated with a “0” value of the pseudo-random bit string. This square-wave signal is passed directly to the transmission electrode, that is to say is applied directly to the transmission electrode, by the signal generation circuit. In this case, “directly” means that no components which significantly change the signal waveform of the transmission signal are interposed between the signal generation circuit and the transmission electrode. However, within the scope of the invention, components which leave the signal waveform of the square-wave signal unchanged, for example one or more amplifiers and/or—in the case of a plurality of transmission electrodes—a multiplex circuit which passes the transmission signal to the plurality of transmission electrodes in a temporally alternating manner, can be interposed between the signal generation circuit and the at least one transmission electrode.

A pseudo-random bit string is understood as meaning a sequence of binary (bit) values (“0” and “1”) which gives the impression of a random bit string which therefore does not reveal any regularity. The sequence has a finite length and is continuously repeated. However, this length is selected to be sufficiently large that the cycle time for processing the entire sequence exceeds the typical time scale of a measurement or an associated series of measurements. As a result, the repetition of the bit string cannot be regularly observed using metrology.

The transmission signal which corresponds directly to the pseudo-random bit string therefore does not have any periodic components on measurement-relevant time scales. As a result, the transmission signal according to the invention differs, in particular, from signals which have a predefined transmission frequency at least at intervals of time or are generated by modulating a frequency spreading signal onto a fundamental frequency. On account of the aperiodicity of the transmission signal, a particularly high degree of immunity of the sensor to interference from spurious signals is achieved, on the one hand. On the other hand, as a result of the pseudo-random bit string being output directly to the transmission electrode, the sensor manages without a frequency generator, in particular without an oscillator, as a result of which the structure of the sensor can be considerably simplified.

In order to process the reception signal generated in the at least one reception electrode, the sensor comprises a downstream reception circuit in an expedient refinement. In order to be able to separate the signal components caused by the aperiodic transmission signal from interference signals in a simple and effective manner from the reception signal, this reception circuit, in an expedient refinement of the sensor, is in the form of a synchronous demodulator which demodulates the pseudo-random bit string corresponding to the transmission signal from the reception signal.

For this purpose, the reception circuit expediently comprises a mixer in which the reception signal is mixed with the transmission signal in order to generate a mixed signal. The resulting mixed signal is supplied to a capacitance measuring element. In a simple and advantageous refinement of the sensor, the mixer is formed by a multiplier, in particular.

In order to eliminate radio-frequency interference signals in the reception signal and therefore to prefilter the reception signal, a low-pass filter is preferably interposed between the reception electrode and the mixer.

In a design which can be implemented in a particularly simple manner in terms of circuitry, the signal generation circuit comprises a linear feedback shift register for generating the pseudo-random square-wave pulse signal. Alternatively, the signal generation circuit is formed by a microcontroller in which a pseudo-random number generator is implemented using software. In both cases, the pseudo-random bit value generation is preferably initiated (triggered) by a clock signal which is in turn aperiodic. When implementing the signal generation circuit using circuitry, the clock signal is generated by an aperiodic trigger circuit. The aperiodic trigger circuit is formed, for example, by a noise generator, for example by a zener diode with a limiter. Alternatively, the aperiodic clock signal can also be generated using a microcontroller.

In one advantageous development of the invention, the signal generation circuit is designed to vary the type, length and/or amplitude of the pseudo-random bit string or of the transmission signal on the basis of at least one reference variable characteristic of an environmental or interfering influence. For example, the signal generation circuit is configured to:

increase the amplitude of the transmission signal in proportion or incrementally with the magnitude of a detected interference level; and/or

change the type and/or length of the pseudo-random bit string once or repeatedly if interference is detected; for example, the length of the pseudo-random bit string is increased if brief interference in the reception signal is determined.

Additionally or alternatively, within the scope of the invention, the clock signal used to clock the pseudo-random bit string, that is to say to convert the pseudo-random bit string into the transmission signal, can also be varied on the basis of at least one reference variable characteristic of an environmental or interfering influence. In this case, the clock length and/or—in the case of an aperiodic clock signal the aperiodicity, in particular the average variation range of the clock length, can be varied, for example.

Other features which are considered as characteristic for the invention are set forth in the appended claims.

Although the invention is illustrated and described herein as embodied in a capacitive sensor for an anti-collision apparatus and such an apparatus, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a schematic block diagram of an anti-trapping apparatus for detecting and avoiding trapping in the case of a movable vehicle part, having a capacitive sensor which comprises a transmission electrode, a reception electrode, a signal generation circuit connected upstream of the transmission electrode and a reception circuit connected downstream of the reception electrode;

FIG. 2 shows a simplified electrical circuit diagram of the structure of the signal generation circuit which is formed in this case by a linear feedback shift register with an upstream aperiodic trigger circuit;

FIG. 3 shows a trigger signal generated by the trigger circuit and a square-wave pulse signal, which is generated by the shift register under the effect of the trigger signal and has pseudo-random variation of the pulse length, in two synchronous graphs with respect to time; and

FIG. 4 shows a simplified electrical circuit diagram of the structure of the reception circuit which is in the form of a synchronous demodulator here and comprises a transimpedance amplifier with a downstream mixer and a low-pass filter which is in turn downstream.

Mutually corresponding parts and variables are provided with the same reference symbols throughout the figures.

### DETAILED DESCRIPTION OF THE INVENTION

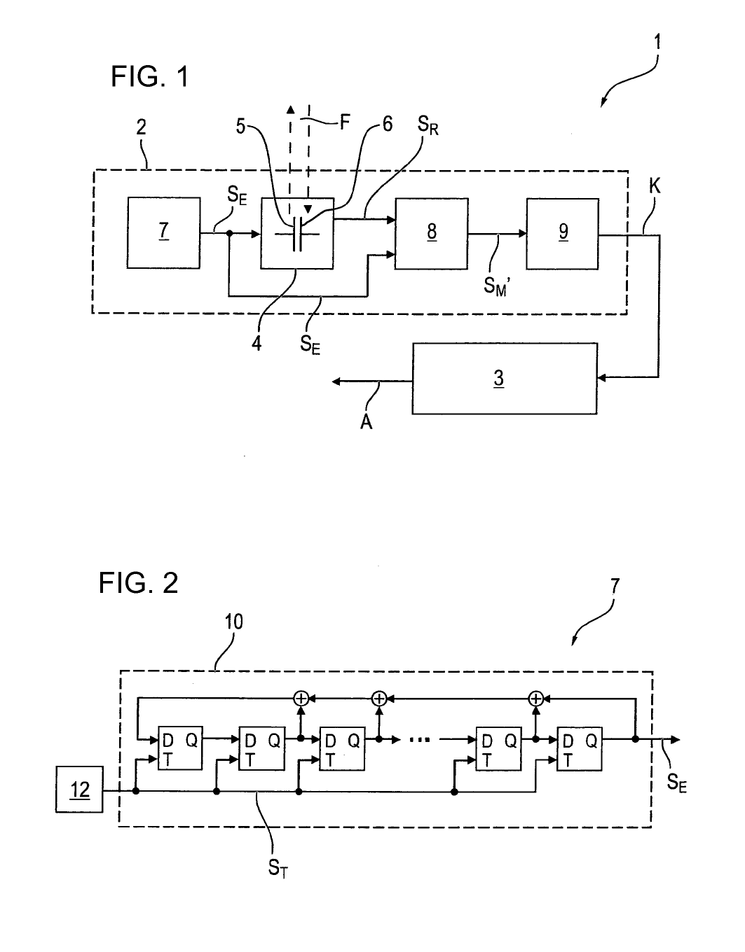

Referring now to the figures of the drawing in detail and first, particularly, to FIG. 1 thereof, there is seen a schematic illustration of an anti-trapping apparatus 1 for a movable adjustment element of a motor vehicle. The movable element may be, in particular, a side window or a door or a tailgate which is moved by a motor. The anti-trapping apparatus 1 comprises a capacitive sensor 2 and a monitoring unit 3.

The sensor 2 is based on capacitive metrology. The sensor 2 accordingly comprises an electrode arrangement 4 having at least one transmission electrode 5 and at least one counter-electrode or reception electrode 6. In a preferred implementation, the electrode arrangement 4 comprises a plurality of transmission electrodes 5 which interact with a common reception electrode 6.

During the operation of the sensor 2, an electric field F is generated in an opening area of the adjustment element by applying an electrical AC voltage to the transmission electrode 5, or each transmission electrode 5, while the (electrical) capacitance of the capacitor formed from the field-emitting transmission electrode 5 and the reception electrode 6 is recorded using the reception electrode 6.

In detail, the sensor 2 comprises, in addition to the electrode arrangement 4, a signal generation circuit 7, a reception circuit 8 and a capacitance measuring element 9.

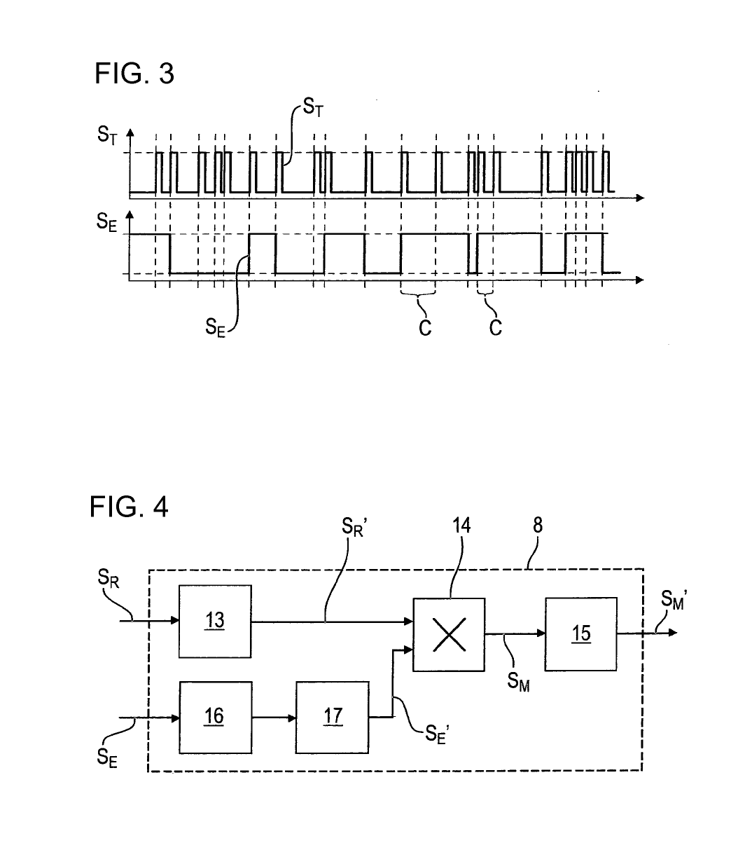

During the operation of the sensor 2, the signal generation circuit 7 generates a transmission signal S_{E} in the form of a square-wave pulse sequence. As indicated in FIG. 3, this square-wave pulse sequence is formed from individual successive clock pulses C, the transmission signal S_{E} being able to assume one of two signal values “high” (for example +5 V) or “low” (for example +0.5 V) in each clock pulse. The sequence of the signal values in the successive clock pulses C therefore directly corresponds to a bit string, the bit value “1” being able to be assigned to the signal value “high” and the bit value “0” being able to be assigned to the signal value “low”, for example.

In this case, the transmission signal S_{E} corresponds to a pseudo-random bit string insofar as the signal values of the successive clock pulses C inside the square-wave pulse sequence are not in a regular relationship. The square-wave pulse sequence comprises several hundred, thousands or tens of thousands of clock pulses C (for example 2¹⁰−1 clock pulses) and is cyclically repeated after processing the entire sequence. On account of the large number of clock pulses, the cycle time for generating and emitting the entire square-wave pulse sequence is more than 0.03 seconds. It therefore considerably exceeds the time needed for an individual measurement (typically of the order of magnitude of 1 ms), with the result that the square-wave pulse sequence appears to be random on measurement-relevant time scales.

With reference to FIG. 2, the signal generation circuit 7 comprises a linear feedback shift register 10 in order to generate the transmission signal S_{E} in the form of a pseudo-random square-wave pulse signal. The shift register 10 is in turn formed by a series circuit of so-called D-type flip-flops 11. In this case, the output Q of the last D-type flip-flop 11 is fed back to the data input D of the first D-type flip-flop 11, the output value from the last D-type flip-flop 11 being added to the respective output values from particular further (but not all) D-type flip-flops 11 of the series circuit in an XOR operation. The D-type flip-flops 11 are synchronously clocked by supplying a clock signal S_{T} via their respective clock input T, the output value from the D-type flip-flop 11 in front in each case being transmitted (shifted) to the following D-type flip-flop 11 with each clock pulse. The output value from the last D-type flip-flop 11 is applied to the at least one transmission electrode 5 as the transmission signal S_{E}.

Referring to FIG. 3, the lower graph shows an exemplary profile of the transmission signal S_{E} on the basis of time t. The upper graph in FIG. 3 shows the temporal profile of the clock signal S_{T} compared with the transmission signal S_{E}.

The clock signal S_{T} is generated by a trigger circuit 12 of the signal generation circuit 7 in the form of an aperiodic pulse signal, in particular a pulse signal with an aperiodically varying pulse interval. The trigger circuit 12 is formed, for example, by a noise generator which is formed by a Zener diode with an associated limiter.

The frequency generator 7 passes the transmission signal S_{E} directly to the transmission electrode 5 which emits the electric field F under the effect of the transmission signal S_{E}. If the sensor 2 comprises a plurality of transmission electrodes 5, a time multiplexer (not illustrated in any more detail) is preferably interposed between the frequency generator 7 and the electrode arrangement 4 and passes the transmission signal S_{E} to one of the plurality of transmission electrodes 5 in each case in a temporally alternating manner.

Under the effect of the electric field F, an electrical alternating signal, which is referred to as the reception signal S_{R} below, is generated in the reception electrode 6. The reception signal S_{R} is in sync with the phase of the transmission signal S_{E}, that is to say has defined switching edges between a high signal level and a low signal level which temporally match the pulse edges of the transmission signal S_{E}. However, in contrast to the transmission signal S_{E}, the signal amplitude of the reception signal S_{R} additionally varies on the basis of the capacitance to be measured.

The reception signal S_{R} is supplied to the reception circuit 8 as an input signal. In this case, a low-pass filter (not explicitly illustrated) for prefiltering the reception signal S_{R} is optionally interposed between the reception electrode 6 and the reception circuit 8.

The reception circuit 8 is in the form of a synchronous demodulator. Accordingly, in addition to the reception signal S_{R}, the transmission signal S_{E} is also supplied to the reception circuit 8 with the circumvention of the electrode arrangement 4.

According to FIG. 4, the reception circuit 8 comprises a transimpedance amplifier 13 for amplifying the reception signal S_{R}. The transimpedance amplifier 13 outputs a voltage signal S_{R}′, which is proportional to the current intensity of the reception signal S_{R}, to a mixer 14 of the reception circuit 8. The transmission signal S_{E} is supplied, as a second input variable, to the mixer 14 which is in the form of a multiplier circuit here. The mixer 14 generates a mixed signal S_{M} by multiplying the voltage signal S_{R}′ by the transmission signal S_{E} and supplies this mixed signal to a downstream low-pass filter 15 of the reception circuit 8. The mixed signal S_{M} substantially corresponds to the multiplication of time-synchronous values of the voltage signal S_{R}′ and a modified transmission signal S_{E}′ (namely adapted in terms of the level and the phase) which is generated from the original transmission signal S_{E} by means of a level converter 16 and a phase shifter 17

S_{M}(t)≈S′_{R}(t)·S′_{E}(t).

The mixed signal S_{M} is adjusted by multiplying it approximately by the influence of the aperiodic transmission signal S_{E} on the profile of the reception signal S_{R}. In the case of a small phase offset of the voltage signal S_{R}′ with respect to the transmission signal S_{E} and on account of external interference, the mixed signal S_{M} often contains radio-frequency signal components, however. These signal components are eliminated in a low-pass filter 15 of the reception circuit 8, which low-pass filter is connected downstream of the mixer 14.

The profile of a filtered mixed signal S_{M}′ output by the low-pass filter 15 is decisively determined by the change in the capacitance between the transmission electrode 5 and the reception electrode 6. This filtered mixed signal S_{M}′ is supplied to the capacitance measuring element 9 which is connected downstream of the reception circuit 8 and generates a measurement variable K proportional to the capacitance from the filtered mixed signal S_{M}′.

The measurement variable K is supplied to the monitoring unit 3 connected downstream of the sensor 2. The monitoring unit 3 which is preferably formed by a microcontroller with monitoring software implemented therein compares the measurement variable K with a stored trigger threshold value. If the threshold value is exceeded, the monitoring unit 3 outputs a trigger signal A which indicates possible trapping and under the effect of which the movement of the adjustment element associated with the anti-trapping apparatus 1 is reversed.

In another embodiment of the anti-trapping apparatus 1, which is not explicitly illustrated in detail, the signal generation circuit 7 is differently formed by a microcontroller. The pseudo-random bit string and the square-wave pulse signal corresponding to the latter are not generated in this case by a shift register or other circuitry means. Rather, the pseudo-random square-wave pulse signal is generated by a pseudo-random number generator which is implemented in the microcontroller using software and is called in continuous repetition by a program loop. Since a changing number of processes with a fluctuating resource requirement are usually processed in a parallel manner in a microcontroller and a fluctuating computing power is therefore available to the random generator under normal circumstances, the random numbers are also regularly generated in this exemplary embodiment in a clock sequence with an aperiodically fluctuating clock length. The microcontroller therefore supports the randomness of the transmission signal by means of aperiodic clocking of the random number generator. The random number generation is expediently given a low priority for this purpose, as a result of which the random numbers are regularly provided by the microcontroller in a time frame with considerable aperiodic fluctuations.

It will be understood that the subject matter of the invention is not restricted to the exemplary embodiments described above. Rather, further embodiments of the invention may be derived from the above description by those of skill in the pertinent art.

The following is a summary list of reference numerals and the corresponding structure used in the above description of the invention:
1 Anti-trapping apparatus
2 Sensor
3 Monitoring unit
4 Electrode arrangement
5 Transmission electrode
6 Reception electrode
7 Signal generation circuit
8 Reception circuit
9 Capacitance measuring element
10 (Linear feedback) shift register
11 D-type flip-flop
12 Trigger circuit
13 Transimpedance amplifier
14 Mixer
15 Low-pass filter
16 Level converter
17 Phase shifter
A Trigger signal
C Clock pulse
t Time
D Data input
F (Electrical) field
k Measurement variable
Q Output
S_{E} Transmission signal
S_{E}′ (Modified) transmission signal
S_{M} Mixed signal
S_{M}′ (Filtered) mixed signal
S_{R} Reception signal
S_{R}′ Voltage signal
S_{T} Clock signal
T Clock input

1. A capacitive sensor detecting an object, the capacitive sensor comprising:
an electrode arrangement having at least one transmission electrode and at least one reception electrode;
a signal generation circuit connected upstream of said at least one transmission electrode, said signal generation circuit being configured to generate a transmission signal in the form of a square-wave pulse signal that directly corresponds to a pseudo-random bit string and to pass the transmission signal to said transmission electrode.

2. The capacitive sensor according to claim 1, which further comprises a reception circuit connected downstream of said at least one reception electrode and configured to process a reception signal generated in said at least one reception electrode, said reception circuit being a synchronous demodulator for demodulating from the reception signal the pseudo-random bit string corresponding to the transmission signal.

3. The sensor according to claim 2, wherein said reception circuit comprises a mixer for mixing the reception signal with the transmission signal in order to generate a mixed signal, and further comprising a capacitance measuring element disposed to receive the mixed signal.

4. The sensor according to claim 3, wherein said mixer is a multiplier.

5. The sensor according to claim 3, which further comprises a low-pass filter or bandpass filter connected downstream of said mixer and configured for filtering radio-frequency signal components from the mixed signal.

6. The sensor according to claim 3, which further comprises a low-pass filter for prefiltering the reception signal interposed between said at least one reception electrode and said mixer.

7. The sensor according to claim 1, wherein said signal generation circuit comprises a linear feedback shift register for generating the pseudo-random bit string.

8. The sensor according to claim 1, wherein said signal generation circuit is a microcontroller in which a pseudo-random number generator is implemented using software in order to generate the pseudo-random bit string.

9. The sensor according to claim 1, wherein the transmission signal is formed from a sequence of clock pulses, the transmission signal having a signal value corresponding to an associated bit value of the pseudo-random bit string in each clock pulse, the successive clock pulses having an aperiodically varying, temporal clock length.

10. The sensor according to claim 1, wherein said signal generation circuit is configured to vary a type, a length and/or an amplitude of the pseudo-random bit string and/or to vary a clock signal used to convert the pseudo-random bit string into the transmission signal based on at least one reference variable characteristic of an environmental or interfering influence.

11. The sensor according to claim 1, configured for detecting an impending collision with a movable vehicle part.

12. The sensor according to claim 1, configured for an anti-trapping device in a motor vehicle.

13. An anti-collision apparatus, comprising a capacitive sensor according to claim 1.
